(19) United States
(12) Patent Application Publication
(10) Pub. No.: US 2020/0152426 A1
(43) Pub. Date: May 14, 2020

(54) SEMICONDUCTOR REACTOR AND METHOD FOR FORMING COATING LAYER ON METAL BASE MATERIAL FOR SEMICONDUCTOR REACTOR

(71) Applicant: KOREA INSTITUTE OF SCIENCE AND TECHNOLOGY, Seoul (KR)

(72) Inventors: Jung Man DOH, Seoul (KR); Young Jun CHOI, Seoul (KR); Jin Kook YOON, Seoul (KR); Seung Hee HAN, Seoul (KR); Byung Yong YU, Seoul (KR)

(21) Appl. No.: 16/476,574

(22) PCT Filed: Jan. 9, 2018
(86) PCT No.: PCT/KR2018/000436

§ 371 Date: Jul. 9, 2019

(30) Foreign Application Priority Data
Jan. 9, 2017 (KR) 10-2017-0003064

(51) Int. Cl. H01J 37/32; C25D 7/00; C25D 9/04; H01L 21/67

(52) U.S. Cl. CPC H01J 37/32495; H01L 21/67069; C25D 9/04; C25D 7/00

(57) ABSTRACT

A method for forming a coating layer on a metal base material for a semiconductor reactor according to an aspect of the present invention comprises the steps of: immersing a metal base material for a semiconductor reactor in an aqueous alkaline electrolyte solution containing NaOH and NaAlO₂; and connecting an electrode to the metal base material and supplying power to the electrode to form a coating layer on the metal base material through a plasma electrolytic oxidation (PEO) method.

### TECHNICAL FIELD

The present invention relates to a semiconductor manufacturing apparatus, and particularly, to a semiconductor reactor of which corrosion resistance and erosion resistance under reactive plasma environments may be improved, and a coating layer thereof.

### BACKGROUND ART

In a semiconductor manufacturing process, a plasma generating apparatus is increasingly adopted for removing the oxide layer on the surface of a silicon wafer and in micro etching processing process. In the semiconductor manufacturing process using plasma, highly corrosive elements such as boron chloride (BCl), carbon tetrafluoride (CF₄), and sulfur hexafluoride (SF₆) are primarily used. In this case, corrosion or erosion may arise in parts exposed to plasma environments such as excited ions, dissociated molecules and radicals, which are produced by plasma discharge, and compounds formed by the reaction with the parts may contaminate the parts or an apparatus to degrade the performance and reliability of the semiconductor.

Accordingly, in order to solve such problems, an inner liner of a plasma reactor, which has excellent plasma resistance properties is acutely required. Materials used for an apparatus for manufacturing a semiconductor, which are exposed to plasma environments include various materials including stainless steel, aluminum, quartz, alumina, silicon carbide, etc.

In order to protect the surface of an apparatus for generating plasma and a part for passing a gas, which are used in a manufacturing process of a semiconductor, a method of forming corrosion resistant and erosion resistant oxide layer on the surface of a valve metal (Al, Mg, Ti, Ta, Hf, Nb, W, Zr, etc.) has been adopted. However, in an amorphous oxide layer formed by a hard-anodizing method, there are basic defects of generating cracks at edges or protruded parts having a small radius of curvature, and in addition, exfoliation problems of a coating layer during practical use may arise. In addition, in case of using a material containing a precipitate such as copper and silicate, it is difficult to form a uniform oxide coated film layer by the anodizing method, and thus, a metal base material which may be used in anodizing is limited.

### DISCLOSURE OF THE INVENTION

### Technical Problem

The present invention is for solving various limitations including the above-described problems, and has an object in providing a method for forming a coating layer on the surface of a metal base material for a semiconductor reactor, which may increase corrosion resistance and erosion resistance to plasma and decrease inner contamination. However, such task is for illustration, and the scope of the present invention is not limited thereto.

### Technical Solution

A method for forming a coating layer on a surface of a metal base material for a semiconductor reactor according to an aspect of the present invention includes a step of immersing a metal base material for a semiconductor reactor in an aqueous alkaline electrolyte solution containing NaOH and NaAlO₂; and a step of connecting an electrode to the metal base material and supplying power to the electrode to form a coating layer on the metal base material through a plasma electrolytic oxidation (PEO) method.

In the method for forming a coating layer, the metal base material may include an aluminum alloy,

the electrolyte may further include an yttrium salt, and the coating layer may include an aluminum oxide layer therein and a composite oxide layer of an aluminum oxide and an yttrium oxide at a surface thereof.

In the method for forming a coating layer, the composite oxide layer may further include an aluminum-yttrium oxide.

In the method for forming a coating layer, the electrolyte may include Y(NO₃)₃ as the yttrium salt.

In the method for forming a coating layer, in the step of forming the coating layer, a bipolar pulse current, which has longer application time of a negative voltage than application time of a positive voltage, may be applied for the plasma electrolytic oxidation.

In the method for forming a coating layer, in the step of forming the coating layer, negative current density of the bipolar pulse current may be greater than positive current density.

In the method for forming a coating layer, the metal base material may include an aluminum alloy containing 0.5 wt % or less (greater than 0 wt %) of copper (Cu) and 0.5 wt % or less (greater than 0 wt %) of silicon (Si) in order to decrease contents of copper (Cu) and silicon (Si) in the coating layer.

In the method for forming a coating layer, the aluminum alloy may include 0.5 wt % or less (greater than 0 wt %) of copper (Cu), 0.5 wt % or less (greater than 0 wt %) silicon (Si), and 1.0-50 wt % of magnesium (Mg) in order to increase a content of magnesium (Mg) in the coating layer.

In the method for forming a coating layer, the aluminum alloy may include 0.2 wt % or less (greater than 0 wt %) of copper (Cu), 0.4 wt % or less (greater than 0 wt %) of silicon (Si), and 2.0-50 wt % of magnesium (Mg), and in the coating layer, a potassium concentration may be 0.1 wt % or less, a copper concentration may be 0.1 wt % or less, and a silicon concentration may be 0.5 wt % or less.

A semiconductor reactor according to another aspect of the present invention includes a metal base material; and a coating layer formed on the metal base material through a plasma electrolytic oxidation (PEO) method. The coating layer may be formed by connecting an electrode to the metal base material and supplying power to the electrode in a state of immersing the metal base material in an aqueous alkaline electrolyte solution containing NaOH and NaAlO₂ through a plasma electrolytic oxidation (PEO) method.

In the semiconductor reactor, the metal base material may include an aluminum alloy, the electrolyte may further include an yttrium salt, and the coating layer may include an aluminum oxide layer therein, and include a composite oxide layer of an aluminum oxide and an yttrium oxide at a surface thereof.

In the semiconductor reactor, the aluminum alloy may include 0.5 wt % or less (greater than 0 wt %) of copper (Cu), and 0.5 wt % or less (greater than 0 wt %) of silicon (Si), and may include crystalline α-Al₂O₃ and γ-Al₂O₃, where a potassium concentration of the coating layer is 0.1 wt % or less, a copper concentration is 0.1 wt % or less, and a silicon concentration is 0.5 wt % or less.

In the semiconductor reactor, the aluminum alloy may include 0.5 wt % or less (greater than 0 wt %) of copper (Cu), and 0.5 wt % or less (greater than 0 wt %) of silicon (Si), and may include a Al—Y—O-rich composite oxide layer, where a potassium concentration at the surface part of the coating layer is 0.1 wt % or less, and an yttrium oxide concentration is 10.0 wt % or more.

In the semiconductor reactor, a thickness of the coating layer may be in a range of 20 to 100 μm.

### Advantageous Effects

According to the method for coating a metal base material for a semiconductor reactor according to an embodiment of the present invention, configured as described above, plasma corrosion resistance and erosion resistance of a coating layer may be markedly improved and contamination by harmful ingredients in the semiconductor reactor may be decreased. The scope of the present invention is not limited to the effects, of course.

### BRIEF DESCRIPTION OF THE DRAWINGS

FIG. 1 is a scanning electron microscope (SEM) photograph showing the cross-section of a specimen formed according to an experimental embodiment of the present invention.

FIG. 2 is a SEM photograph showing the cross-section of a specimen formed according to another experimental embodiment of the present invention.

FIG. 3 shows SEM photographs showing the microstructure and concentration distribution of the cross-section of the specimen of FIG. 2.

### MODE FOR CARRYING OUT THE INVENTION

Hereinafter, embodiments of the present invention will be explained in detail with reference to attached drawings. However, the present invention is not limited to the embodiments disclosed hereinafter and may be accomplished in various different forms. The embodiments hereinafter are provided for completing the disclosure of the present invention and informing the scope of the present invention to a person skilled in the art. In addition, for convenience of explanation, the size of constituent elements in drawings may be exaggerated or downsized.

In embodiments of the present invention, the semiconductor reactor may be understood as a part for performing reaction such as deposition and etching in an apparatus for manufacturing a semiconductor. For example, the semiconductor reactor may be understood to include a reaction space of an apparatus for manufacturing a semiconductor using plasma, for example, a plasma chamber.

In embodiments of the present invention, the metal base material of the semiconductor reactor may be one of valve metals (Al, Mg, Ti, Ta, Hf, Nb, W, Zr, etc.). In some embodiments, the metal base material of the semiconductor reactor may be an aluminum (Al) alloy.

According to embodiments of the present invention, in order to solve the problems of the conventional anodizing, a plasma electrolytic oxidation process (PEO) is used for producing an oxide layer having even better corrosion resistance and erosion resistance with respect to plasma. The PEO method is a surface treatment method by which a metal surface immersed in an electrolyte is oxidized, and plasma arc is generated at the surface of an oxide layer to bake the oxide layer with heat of a high temperature, thereby increasing hardness and improving corrosion resistance, erosion resistance and heat resistance. In case of using the plasma electrolytic oxidation process, an oxide layer may be formed densely on the surface of the valve metal.

Elements included in the metal base material and coating layer of an apparatus for manufacturing a semiconductor device, such as copper (Cu), silicon (Si) and potassium (K), contaminate a silicon wafer and the inside of a reactor to induce harmful effects, but magnesium (Mg) reacts with a halogen gas to form a safe oxide so as to play the role of protecting a surface oxide layer. Copper and silica precipitates restrain the formation of a uniform coating layer, copper eluted from a PEO coating layer in a reactive plasma atmosphere contaminates a silicon substrate and an apparatus for manufacturing a semiconductor, and silica (SiO₂) injected into a crystalline alumina coating layer forms an amorphous phase to degrade corrosion resistance and erosion resistance of the PEO coating layer. Accordingly, in the metal base material of the reactor and surface coating layer, if copper, silicon and potassium components are decreased as far as possible and a magnesium component is increased, the contamination of the silicon wafer and the inside of the reactor may be decreased, and the life of a semiconductor manufacturing apparatus may be increased.

The contents of copper (Cu), silicon (Si), potassium (K), etc., which exert harmful effects to a semiconductor part and a silicon substrate for manufacturing a semiconductor device are shown high at the outermost surface part when compared with the inside of the PEO coating layer. Accordingly, in order to decrease the contents of harmful elements (Cu, Si, K, etc.) in the surface part of the PEO coating layer, a metal base material having small contents of Cu and Si is required, and a PEO electrolyte not including K and Si is required to be selected.

Therefore, the method for forming a coating layer on a metal base material for a semiconductor reactor according to an embodiment of the present invention may include a step of immersing a metal base material for a semiconductor reactor in an electrolyte, and a step of connecting an electrode to the metal base material and supplying power to the electrode to form a coating layer on the metal base material through a plasma electrolytic oxidation (PEO) method. By using such a PEO method, a structure in which a coating layer is formed on a metal base material, for example, an apparatus for manufacturing a semiconductor or its part, for example, a semiconductor reactor or a plasma chamber may be manufactured.

For example, an aqueous alkaline solution may be used as an electrolyte for the plasma electrolytic oxidation of a semiconductor part such as a semiconductor reactor. The component and additive of the electrolyte may be selected for controlling electrolysis conditions and the quality of a coating layer.

In embodiments of the present invention, in order to restrain the mixing of potassium (K) in the coating layer as a harmful element, NaOH may be used instead of the conventional KOH in an electrolyte. In case of using an electrolyte containing NaOH, sodium (Na) employed in the coating layer and aluminum (Al) of a metal base material may react with a fluorine (F) gas used in a semiconductor to produce a NaF—AlF₃ reaction salt (see NaF—AlF₃ phase diagram). The melting point of the NaF—AlF₃ reaction salt is higher by about 100° C. than the melting point of a KF—AlF₃ reaction salt, which is produced by the reaction of potassium (K) employed in the coating layer, in case of using an electrolyte containing KOH, and aluminum (Al) of a metal base material with a fluorine (F) gas. Accordingly, the heat resistance of a PEO coating layer formed in an electrolyte using NaOH is improved by about 100° C. than the heat resistance of a PEO coating layer formed in an electrolyte using KOH.

In some embodiments of the present invention, NaOH and NaAlO₂ may be included at the same time in an electrolyte. Such an electrolyte is more effective in improving the heat resistance of a coating layer due to the addition of NaOH, and may contribute to the increase of a coating rate. For example, the thickness of a coating layer according to such embodiment may be several tens to several hundreds μm, and further in a range of 20 to 100 μm so as to be appropriately used for a semiconductor reactor.

In some embodiments of the present invention, the electrolyte may include an yttrium salt as an additive. For example, the electrolyte may include Y(NO₃)₃ as the yttrium salt. For example, an electrolyte including NaOH, NaAlO₂ and Y(NO₃)₃ may be used for forming the PEO coating layer of an aluminum alloy. Yttrium added to the electrolyte may form an yttrium oxide in the coating layer in a plasma electrolytic oxidation step. In this case, the coating layer includes a crystalline aluminum oxide layer therein and may include a composite oxide layer of an aluminum oxide and an yttrium oxide at the surface thereof. Such a composite oxide or yttrium oxide at the surface part may even further increase the corrosion resistance and erosion resistance to plasma of the coating layer.

In the above-described embodiments, the electrolyte may further include an organic binder in addition to the above-described components.

In some embodiments of the present invention, electrolysis conditions may be controlled to increase the growth rate and quality of the PEO coating layer. For example, in a step of forming a coating layer using plasma electrolytic oxidation, bipolar pulse current which has longer application time of a negative voltage than the application time of a positive voltage may be applied. Further, the negative current density of the bipolar pulse current may be controlled to be greater than the positive current density.

In some embodiments of the present invention, in order to control the composition in the coating layer, the component and content of the metal base material may be controlled. For example, in order to decrease the contents of copper (Cu) and silicon (Si) in the coating layer, the metal base material may include an aluminum alloy containing 0.5 wt % or less (greater than 0 wt %) of copper (Cu) and 1.0 wt % or less (greater than 0 wt %) of silicon (Si). Preferably, in order to limit the influence of such copper and silicon further, the copper content in the aluminum alloy may be limited to 0.25 wt % or less, more restrictively, 0.1 wt % or less. Further, the silicon content may be limited to 0.5 wt % or less, more strictly, 0.4 wt % or less.

Further, in order to increase the magnesium (Mg) content in the coating layer to form a protective coated film for protecting the coating layer, the aluminum alloy which is used as the metal base material may further contain 1.0-50 wt % of magnesium (Mg). In some embodiments, the aluminum alloy may contain 0.2 wt % or less (greater than 0 wt %) of copper (Cu), 0.4 wt % or less (greater than 0 wt %) of silicon (Si) and 1.5-50 wt % of magnesium (Mg). More restrictively, a copper concentration may be further limited to 0.1 wt % or less, and the magnesium content may become 2.0-50 wt % by raising the lower limit.

More particularly, as the metal base material, an aluminum alloy of which copper concentration is 0.5 wt % or less and silicon concentration is 1.0 wt % or less, preferably, an aluminum alloy of which copper concentration is 0.25 wt % or less and silicon concentration is 0.5 wt % or less, more preferably, an aluminum alloy of which copper concentration is 0.15 wt % or less and silicon concentration is 0.4 wt % or less, may be used. In addition, as the metal base material, an aluminum alloy of which copper concentration is 0.5 wt % or less, silicon concentration is 1.0 wt % or less, and magnesium concentration is 1.0-50 wt %, preferably, an aluminum alloy of which copper concentration is 0.25 wt % or less, silicon concentration is 0.5 wt % or less, and magnesium concentration is 1.5-50 wt %, more preferably, an aluminum alloy of which copper concentration is 0.1 wt % or less, silicon concentration is 0.4 wt % or less, and magnesium concentration is 2.0-50 wt %, may be used.

As the aluminum alloy, a developed alloy or a common alloy, which has such compositions may be used. For example, among the common aluminum alloy, A5052, A5082, A5083, A5086 alloy, etc., which have low copper and silicon concentrations and high magnesium concentration may be used as the metal base material.

As described above, by limiting the component and composition of the metal base material, the mixing amounts of copper and silicon in the coating layer may be decreased and the mixing amount of magnesium may be increased. Accordingly, the plasma resistance properties of a semiconductor reactor using such a metal base material and coating layer may be improved, and the mixing of harmful impurities, etc., into a semiconductor device from the semiconductor reactor may be restrained, thereby increasing the reliability of the semiconductor reactor and improving life.

In some embodiments of the present invention, by decreasing or excluding the mixing of silicon (Si) in an electrolyte prior to PEO coating, and by using an aluminum metal base material having a low silicon concentration, the degradation of crystallinity by the mixing of amorphous silica (SiO₂) into a crystalline Al₂O₃ alumina coating layer during a PEO process may be restrained, and problems of decreasing the corrosion resistance and erosion resistance of the coating layer due to a silicate may be solved.

Meanwhile, a crystalline oxide is known to show excellent corrosion resistance and erosion resistance than an amorphous oxide in plasma environments. According to the above-described embodiments, by decreasing the copper content in the metal base material and decreasing the potassium content in the electrolyte during PEO coating, the crystallinity of alumina in the coating layer may be increased, and the plasma corrosion resistance and erosion resistance may be improved.

Hereinafter, experimental examples according to the present invention and comparative examples will be explained in comparison.

### Experimental Example 1

A flat plate-type A5083 aluminum alloy having a size of 50 mm×50 mm×5 mm, i.e., an area of 6,000 mm² was prepared. The A5083 aluminum alloy thus prepared was immersed in an aqueous alkaline solution kept to 10° C., and then, an anode was connected to a specimen. Here, the aqueous alkaline solution contained 2 g/l of NaOH, 2 g/l of NaAlO₂ and an organic additive. By using a bipolar pulse direct current power equipment, the A5083 aluminum alloy connected to the anode was PEO coating treated for 1 hour. That is, to the A5083 aluminum alloy, positive current of 5 A/dm² was applied for 8,000 μs, and negative current of 6 A/dm² was applied for 11,000 μs.

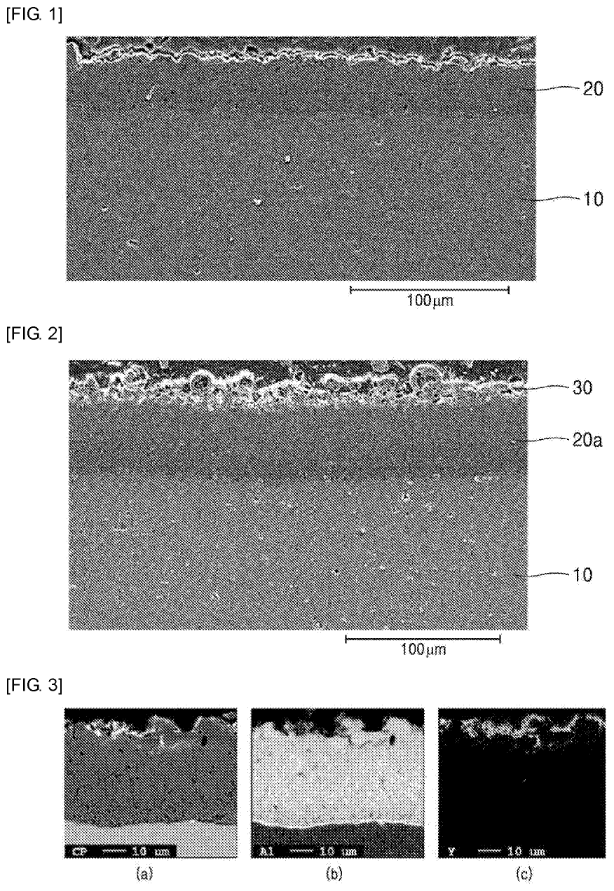

In FIG. 1, a scanning electron microscope photograph of the cross-sectional structure of an oxide layer of the surface of the A5083 aluminum alloy formed according to Experimental Example 1 is shown.

Referring to FIG. 1, it could be confirmed that on the surface of a A5083 aluminum alloy (10), which was a metal base material, an Al₂O₃ alumina oxide layer (20) was formed as a coating layer. Here, the Al₂O₃ alumina oxide layer (20) was uniformly formed on the surface of the A5083 aluminum alloy (10), and its texture was densified. The Al₂O₃ alumina oxide layer (20) was composed of α-Al₂O₃ and γ-Al₂O₃, and the porosity of the alumina oxide layer was about 5% or less, and a very dense microstructure was obtained. As a result of quantizing the components of the coating layer by EPMA, the coating layer was composed of a crystalline Al₂O₃ alumina coating layer in which the copper concentration at the surface part of the coating layer was 0.03 wt %, which was 0.1 wt % or less, the silicon concentration was 0.34 wt %, which was 0.5 wt % or less, the potassium concentration was 0.02 wt %, and the magnesium concentration was 2.31 wt %, which was 2.0 wt % or more. The thickness of the crystalline Al₂O₃ alumina oxide layer (20) containing 2.0 wt % or more of magnesium was about 33 μm or more. The thickness of the crystalline Al₂O₃ alumina oxide layer (20) containing 2.0 wt % or more of magnesium was about 33 μm or more.

### Experimental Example 2

A flat plate-type A5083 aluminum alloy having a size of 50 mm×50 mm×5 mm, i.e., an area of 6,000 mm² was prepared. The A5083 aluminum alloy thus prepared was immersed in an aqueous alkaline solution kept to 10° C., and then, an anode was connected to a specimen. Here, the aqueous alkaline solution contained 2 g/l of NaOH, 2 g/l of NaAlO₂, 1.5 g/l of Y(NO₃)₃, and an organic additive. By using a bipolar pulse direct current power equipment, the A5083 aluminum alloy connected to the anode was PEO coating treated for 1 hour. That is, to the A5083 aluminum alloy, positive current of 5 A/dm² was applied for 8,000 μs, and negative current of 6 A/dm² was applied for 11,000 μs.

In FIG. 2, a scanning electron microscope photograph of the cross-sectional structure of an oxide layer of the surface of the A5083 aluminum alloy formed according to Experimental Example 2 is shown.

Referring to FIG. 2, it could be confirmed that on a A5083 aluminum alloy (10), which was a metal base material, a crystalline Al₂O₃ alumina oxide layer (20a) and an Al—Y—O-rich composite oxide layer (30) were formed as coating layers. The outermost Al—Y—O-rich composite oxide layer (30) was somewhat nonuniformly formed. As a result of quantizing the contents of the PEO coating layer by EPMA, the surface part of the coating layer was composed of a composite coating layer in which the copper concentration was 0.37 wt %, which was 0.5 wt % or less, the silicon concentration was 0.45 wt %, which was 0.5 wt % or less, the potassium concentration was 0.03 wt %, which was 0.1 wt % or less, the magnesium concentration was 0.27 wt %, and the yttria concentration was 70.6 wt %. From this, the potassium concentration in the coating layer could be controlled to low and 0.1 wt % or less (greater than 0 wt %), the copper concentration could be controlled to low and 0.1 wt % or less (greater than 0 wt %), and the silicon concentration was controlled to low and 0.5 wt % or less (greater than 0 wt %). Further, preferably, at least one among potassium, copper and silicon may be rarely detected. In addition, the concentration of yttrium oxide in the surface part of the coating layer may be high and 10.0 wt % or more, further, 50.0 wt % or more.

As a result of an XRD analysis, the PEO coating layer was composed of a composite oxide layer composed of crystalline Al₂O₃, Y₂O₃, Y₄Al₂O₉, etc., which had excellent corrosion resistance and erosion resistance to reactive plasma.

The thickness of the crystalline Al₂O₃ alumina oxide layer (20a) in the PEO was about 48 μm, and the thickness of the Al—Y—O-rich composite oxide layer (30) at the outermost surface part of the PEO coating layer was about 18.8 μm.

In FIG. 3, (a) shows a micro texture according to Experimental Example 2, (b) shows aluminum concentration distribution on a cross-section, and (c) shows yttrium concentration distribution. From this, it could be found that yttrium oxide or Al₂O₃—Y₂O₃ or Al₂O₃—Y₄Al₂O₉ or Y₂O₃—Y₄Al₂O₉ or Al₂O₃—Y₂O₃—Y₄Al₂O₉ type composite oxide layer (30), which is known to have excellent erosion resistance to plasma, is mainly concentrated at the outermost surface part of the PEO coating layer.

### Comparative Example 1

A flat plate-type A5083 aluminum alloy having a size of 50 mm×50 mm×5 mm, i.e., an area of 6,000 mm² was prepared. The A5083 aluminum alloy thus prepared was immersed in an aqueous alkaline solution kept to 10° C., and then, an anode was connected to a specimen. Here, the aqueous alkaline solution contained 2 g/l of KOH, 4 g/l of Na₂SiO₃ and an organic additive. By using a bipolar pulse direct current power equipment, the A5083 aluminum alloy connected to the anode was PEO coating treated for 1 hour. That is, to the A5083 aluminum alloy, positive current of 5 A/dm² was applied for 8,000 μs, and negative current of 6 A/dm² was applied for 11,000 μs.

As a result of EDS analysis on a coating layer formed at the surface of a metal base material by Comparative Example 1, the copper concentration was 0.03 wt %, the silicon concentration was 21.16 wt %, the potassium concentration was 4.4 wt %, and the magnesium concentration was 1.63 wt %, and the concentrations of potassium and silicon were very high. As described above, the PEO coating layer having the high silicon content induces basic problems of inferior corrosion resistance and erosion resistance in a reactive plasma atmosphere to a crystalline alumina layer with high purity.

### Comparative Example 2

A flat plate-type A5083 aluminum alloy having a size of 50 mm×50 mm×5 mm, i.e., an area of 6,000 mm² was prepared. The A5083 aluminum alloy thus prepared was immersed in an aqueous alkaline solution kept to 10° C., and then, an anode was connected to a specimen. Here, the aqueous alkaline solution contained 2 g/l of KOH. By using a bipolar pulse direct current power equipment, the A5083 aluminum alloy connected to the anode was PEO coating treated for 1 hour. That is, to the A5083 aluminum alloy, positive voltage of 480 V was applied for 100 μs, and negative voltage of 300 V was applied for 1000 μs. As a result, the thickness of the coating layer thus obtained was about 3-4 μm, and the growing rate of the coating layer was very slow.

### Comparative Example 3

A flat plate-type A5083 aluminum alloy having a size of 50 mm×50 mm×5 mm, i.e., an area of 6,000 mm² was prepared. The A5083 aluminum alloy thus prepared was immersed in an aqueous alkaline solution kept to 10° C., and then, an anode was connected to a specimen. Here, the aqueous alkaline solution contained 2 g/l of KOH, and 1 g/l of Y(NO₃)₃. By using a bipolar pulse direct current power equipment, the A5083 aluminum alloy connected to the anode was PEO coating treated for 1 hour. That is, to the A5083 aluminum alloy, positive voltage of 480 V was applied for 100 μs, and negative voltage of 300 V was applied for 1000 μs. As a result, the thickness of the coating layer thus obtained was about 3-5 μm, and the growing rate of the coating layer was very slow.

From the results of Experimental Examples 1 and 2, the formation of a coating layer with a thickness of about 50 μm was possible through the PEO coating for 1 hour by the coating method according to the present invention, but according to Comparative Examples 1 and 2, the thickness of the PEO coating layer for 1 hour was 3-5 μm, and the formation of a thick coating layer was difficult. From the above-described facts, the conventional PEO technique using a KOH electrolyte is difficult to apply to an apparatus for manufacturing a semiconductor which is exposed to reactive plasma environments, but the crystalline Al₂O₃ alumina or Al—Y—O-rich composite oxide layer with a thickness of about 50 μm, which is developed in the present invention, is expected to be applied to an apparatus for manufacturing a semiconductor device.

Although the present invention is explained referring to embodiments shown in the drawings, the embodiments are only for illustration, and a person of ordinary skill in the art would understand that various modifications and equivalent other embodiments are possible therefrom. Therefore, true technical protection scope of the present invention should be determined by the technical spirit of the claims attached herein.

1. A method for forming a coating layer on a metal base material for a semiconductor reactor, the method comprising:
a step of immersing a metal base material for a semiconductor reactor in an aqueous alkaline electrolyte solution containing NaOH and NaAlO₂; and
a step of forming a coating layer on the metal base material by a plasma electrolytic oxidation (PEO) method, by connecting an electrode to the metal base material and supplying power to the electrode.

2. The method for forming a coating layer on a metal base material for a semiconductor reactor according to claim 1, wherein the metal base material comprises an aluminum alloy,
the electrolyte further comprises an yttrium salt, and
the coating layer comprises an aluminum oxide layer therein, and comprises a composite oxide layer of an aluminum oxide and an yttrium oxide at a surface thereof.

3. The method for forming a coating layer on a metal base material for a semiconductor reactor according to claim 2, wherein the composite oxide layer further comprises an aluminum-yttrium oxide.

4. The method for forming a coating layer on a metal base material for a semiconductor reactor according to claim 2, wherein the electrolyte comprises Y(NO₃)₃ as the yttrium salt.

5. The method for forming a coating layer on a metal base material for a semiconductor reactor according to claim 1, wherein in the step of forming the coating layer, a bipolar pulse current, which has longer application time of a negative voltage than application time of a positive voltage, is applied for the plasma electrolytic oxidation.

6. The method for forming a coating layer on a metal base material for a semiconductor reactor according to claim 5, wherein in the step of forming the coating layer, negative current density of the bipolar pulse current is greater than positive current density.

7. The method for forming a coating layer on a metal base material for a semiconductor reactor according to claim 1, wherein the metal base material comprises an aluminum alloy containing 0.5 wt % or less (greater than 0 wt %) of copper (Cu) and 0.5 wt % or less (greater than 0 wt %) of silicon (Si) in order to decrease contents of copper (Cu) and silicon (Si) in the coating layer.

8. The method for forming a coating layer on a metal base material for a semiconductor reactor according to claim 7, wherein the aluminum alloy comprises 0.5 wt % or less (greater than 0 wt %) of copper (Cu), 0.5 wt % or less (greater than 0 wt %) silicon (Si), and 1.0-50 wt % of magnesium (Mg) in order to increase a content of magnesium (Mg) in the coating layer.

9. The method for forming a coating layer on a metal base material for a semiconductor reactor according to claim 8, wherein the aluminum alloy comprises 0.2 wt % or less (greater than 0 wt %) of copper (Cu), 0.4 wt % or less (greater than 0 wt %) of silicon (Si), and 2.0-50 wt % of magnesium (Mg), and
in the coating layer, a potassium concentration is 0.1 wt % or less, a copper concentration is 0.1 wt % or less, and a silicon concentration is 0.5 wt % or less.

10. A semiconductor reactor, comprising:
a metal base material; and
a coating layer formed on the metal base material through a plasma electrolytic oxidation (PEO) method,
wherein the coating layer is formed by a plasma electrolytic oxidation (PEO) method, by connecting an electrode to the metal base material and supplying power to the electrode while the metal base material is immersed in an aqueous alkaline electrolyte solution containing NaOH and NaAlO₂.

11. The semiconductor reactor according to claim 10, wherein the metal base material comprises an aluminum alloy,
the electrolyte further comprises an yttrium salt, and
the coating layer comprises an aluminum oxide layer therein, and comprises a composite oxide layer of an aluminum oxide and an yttrium oxide at a surface thereof.

12. The semiconductor reactor according to claim 11, wherein the composite oxide layer further comprises an aluminum-yttrium oxide.

13. The semiconductor reactor according to claim 11, wherein the aluminum alloy comprises 0.5 wt % or less (greater than 0 wt %) of copper (Cu), 0.5 wt % or less (greater than 0 wt %) of silicon (Si), and comprises crystalline α-Al₂O₃ and γ-Al₂O₃, where a potassium concentration of the coating layer is 0.1 wt % or less, a copper concentration is 0.1 wt % or less, and a silicon concentration is 0.5 wt % or less.

14. The semiconductor reactor according to claim 11, wherein the aluminum alloy comprises 0.5 wt % or less (greater than 0 wt %) of copper (Cu), and 0.5 wt % or less (greater than 0 wt %) of silicon (Si), and comprises a Al—Y—O-rich composite oxide layer, where a potassium concentration at the surface part of the coating layer is 0.1 wt % or less, and an yttrium oxide concentration is 10.0 wt % or more.

15. The semiconductor reactor according to claim 11, wherein a thickness of the coating layer is in a range of 20 to 100 μm.
